(19) United States
(12) Patent Application Publication
(10) Pub. No.: US 2011/0155997 A1
(43) Pub. Date: Jun. 30, 2011

(54) Vertical Light emitting diode and manufacturing method of the same

(76) Inventors: Ung Lee, Gyeonggi-do (KR); So-Young Jang, Gyeonggi-do (KR); Sang-Jun Jung, Gyeonggi-do (KR); Hyun-Goo Kim, Daejeon (KR)

(21) Appl. No.: 12/926,839

(22) Filed: Dec. 13, 2010

(30) Foreign Application Priority Data
Dec. 30, 2009 (KR) 10-2009-0134353

(51) Int. Cl. H01L 33/06; H01L 21/20

(52) U.S. Cl. 257/13; 438/29; 257/E33.023; 257/E21.09

(57) ABSTRACT

The vertical light emitting diode includes a substrate having a plurality of penetrating via-holes, a plurality of nitride semiconductor layers formed on the substrate, a first electrode formed on the plurality of nitride semiconductor layers, and a second electrode formed to fill the plurality of via-holes thereby contacting part of the plurality of nitride semiconductor layers.

This application claims the benefit of Korean Patent Application No. P10-2009-0134353, filed on Dec. 30, 2009, which is hereby incorporated by reference.

### BACKGROUND OF THE INVENTION

1. Field of the Invention

The present invention relates to a vertical light emitting diode and a manufacturing method of the same.

2. Discussion of the Related Art

Generally, a light emitting diode (LED) is a special type of light emitting device that emits light when current is applied thereto. Such a light emitting diode, which converts electricity into light using characteristics of chemical compound semiconductors, may operate at a low voltage with high efficiency and thus, has long been known to exhibit outstanding energy saving effects. Recently, a light emitting diode realizes a remarkable improvement in brightness and has been applied to a variety of automated appliances, such as backlight units of liquid crystal displays, electric bulletin boards, displays, electric home appliances, etc.

In particular, a gallium nitride (GaN) based light emitting diode exhibits an infrared spectrum or a wider light emission spectrum including infrared light and has a variety of applications. Furthermore, due to an advantage of containing no environmentally harmful materials, such as arsenic (As), mercury (Hg), etc., the GaN based light emitting diode has lately attracted considerable attention as the next-generation light source.

FIG. 1 is a perspective view illustrating a related art light emitting diode. As illustrated in FIG. 1, the related art light emitting diode 10 includes a sapphire base substrate 11, a first buffer layer 12 formed on the sapphire base substrate 11, a second buffer layer 13 formed on the first buffer layer 12 using an undoped GaN layer 13, an n-type GaN layer 14 formed on the second buffer layer 13, an active layer 15 formed on the n-type GaN layer 14 to have a multi-quantum-well (MQW) structure, a p-type GaN layer 16 formed on the active layer 15, an ohmic contact layer 17 formed on the p-type GaN layer 16 using a transparent conductive material, a p-type electrode pad 18 formed to contact a part of the ohmic contact layer 17, and an n-type electrode pad 19 formed to contact a part of the n-type GaN layer 14 that has been exposed by etching partial regions of the active layer 15, p-type GaN layer 16 and ohmic contact layer 17.

In a related art light emitting diode 10, the sapphire base substrate 11 is essential for the growth of the nitride semiconductor layers 13 to 16 and is formed below the nitride semiconductor layers 13 to 16. In addition, the p-type electrode pad 18 and n-type electrode pad 19, which are wire-bonded respectively to the p-type GaN layer 16 and n-type GaN layer 14 for the sake of voltage application, are horizontally formed on the plurality of nitride semiconductor layers 13 to 16. The related art light emitting diode 10 having the above described configuration has the following problems.

First, current flows in a horizontal direction between the p-type electrode pad 18 and the n-type electrode pad 19 and is concentrated on a certain region because the p-type electrode pad 18 and n-type electrode pad 19 are formed horizontally parallel to each other. This current concentration increases a forward voltage and thus lowers current efficiency and also may cause deterioration of the light emitting diode 10 due to generation of static electricity.

Second, a light emitting area is reduced because partial regions of the active layer 15, p-type GaN layer 16 and ohmic contact layer 17 should be removed to form the n-type electrode pad 19.

Third, the light emitting diode 10 is adapted to emit light from the top of the plurality of nitride semiconductor layers 13 to 16. In this case, since the p-type electrode pad 18 and n-type electrode pad 19 formed on emission paths of light may absorb light, the light output efficiency of the light emitting diode 10 decreases.

Fourth, part of the light generated from the plurality of nitride semiconductor layers 13 to 16 is introduced into the sapphire base substrate 11. In this case, as the light, introduced into the sapphire base substrate 11 by a critical angle or more, is totally reflected and disappears in the interior of the sapphire base substrate 11, the light output efficiency of the light emitting diode 10 decreases.

Fifth, the plurality of nitride semiconductor layers 13 to 16 emit heat simultaneously with generation of light. Since the sapphire base substrate 11 has low heat conductivity and thus, has difficulty discharging heat, the heat generated from the plurality of nitride semiconductor layers 13 to 16 reduces current efficiency.

As described above, the related art light emitting diode 10 suffers deterioration in current efficiency, light output efficiency and lifespan thereof because the p-type electrode pad 18 and n-type electrode pad 19 are formed horizontally parallel to each other. For this reason, a vertical light emitting diode, in which a sapphire base substrate used for the growth of a plurality of nitride semiconductor layers is removed such that a p-type electrode pad and n-type electrode pad are formed respectively above and below the nitride semiconductor layers, has been proposed.

FIG. 2 is a perspective view illustrating a related art vertical light emitting diode. As illustrated in FIG. 2, the related art vertical light emitting diode 20 includes a lower metal substrate 21 serving as a p-type electrode pad, a p-type electrode 22 formed on the lower metal substrate 21, a p-type GaN layer 23 formed on the p-type electrode 22, an active layer 24 formed on the p-type GaN layer 23, an n-type GaN layer 25 formed on the active layer 24, an undoped GaN buffer layer 26 formed on the n-type GaN layer 25, and an n-type electrode 27 formed to contact at least a part of the buffer layer 26.

A manufacturing method of the above described related art vertical light emitting diode 20 will now be described. First, the undoped GaN buffer layer 26, n-type GaN layer 25, active layer 24 and p-type GaN layer 23 are sequentially grown on a sapphire base substrate (not shown). After the p-type electrode 22 is formed on the p-type GaN layer 23 to contact the entire surface of the p-type GaN layer 23, the lower metal substrate 21 is attached to the p-type electrode 22 at a high temperature. Thereafter, the sapphire base substrate (not shown) is separated from the buffer layer 26, and the n-type electrode 27 is formed to contact a part of the buffer layer 26 that has been exposed by removing the sapphire base substrate (not shown). In this case, to remove the sapphire base substrate (not shown), a laser lift off (LLO) process is generally used, in which a laser is irradiated to a surface of the sapphire base substrate (not shown) to separate the sapphire base substrate (not shown) from the buffer layer 26 at a high temperature of 600° C. or more.

As described above, the p-type electrode 22 and n-type electrode 27 may be formed in a vertical direction of the plurality of nitride semiconductor layers 23 to 26 as the sapphire base substrate (not shown) used for the growth of the nitride semiconductor layers 23 to 26 is removed to prevent a reduction in light emitting area, light output efficiency, current efficiency, and current concentration.

However, the manufacturing method of the related art vertical light emitting diode 20 includes a process of removing the sapphire base substrate (not shown), i.e. the laser lift off process. The laser lift off process may increase manufacturing costs due to the use of expensive equipment and also, may complicate the entire manufacturing process as compared to a related art light emitting diode, resulting in increased manufacturing time. Moreover, the laser lift off process may cause damage to the nitride semiconductor layers 23 to 26. In addition, the attachment between the lower metal substrate 21 and the p-type electrode 22 has frequent process errors and becomes a factor of low yield.

### SUMMARY OF THE INVENTION

Accordingly, the present invention is directed to a vertical light emitting diode and a manufacturing method of the same that substantially obviates one or more problems due to limitations and disadvantages of the related art.

An object of the present invention is to provide a vertical light emitting diode and a manufacturing method of the same, in which electrodes may be formed vertically without removing a substrate used for the growth of nitride semiconductor layers.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, the vertical light emitting diode includes a substrate having a plurality of penetrating via-holes, a plurality of nitride semiconductor layers formed on the substrate, a first electrode formed on the plurality of nitride semiconductor layers, and a second electrode formed to fill the plurality of via-holes thereby contacting part of the plurality of nitride semiconductor layers.

In another aspect, the method of manufacturing a vertical light emitting diode includes forming a plurality of via-holes in a substrate, forming a plurality of nitride semiconductor layers on the substrate, forming a first electrode and a first electrode pad on the plurality of nitride semiconductor layers, and forming a second electrode in the plurality of via-holes to contact part of the plurality of nitride semiconductor layers exposed through the plurality of via-holes.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a perspective view illustrating a related art light emitting diode;

FIG. 2 is a perspective view illustrating a related art vertical light emitting diode;

FIG. 3 is a perspective view illustrating a vertical light emitting diode according to an exemplary embodiment of the present invention;

FIG. 4 is a sectional view taken along the line A-A′ in FIG. 3;

FIGS. 5A to 5D are views illustrating current distribution in corresponding active layers of a related art light emitting diode and the vertical light emitting diode according to the exemplary embodiment of the present invention;

FIGS. 6A to 6D are views illustrating light power output from corresponding upper surfaces of the related art light emitting diode and the vertical light emitting diode according to the exemplary embodiment of the present invention;

FIGS. 7A and 7B are graphs illustrating light power output based on the applied current in the related art light emitting diodes and the vertical light emitting diodes according to the exemplary embodiment of the present invention;

FIG. 8 is a flow chart illustrating a manufacturing method of the vertical light emitting diode according to the exemplary embodiment of the present invention; and

FIGS. 9A to 9G are sectional views illustrating sequential processes of the manufacturing method of the vertical light emitting diode shown in FIG. 8.

### DETAILED DESCRIPTION OF THE PREFERRED EMBODIMENTS

Reference will now be made in detail to the preferred embodiments of the present invention, examples of which are illustrated in the accompanying drawings.

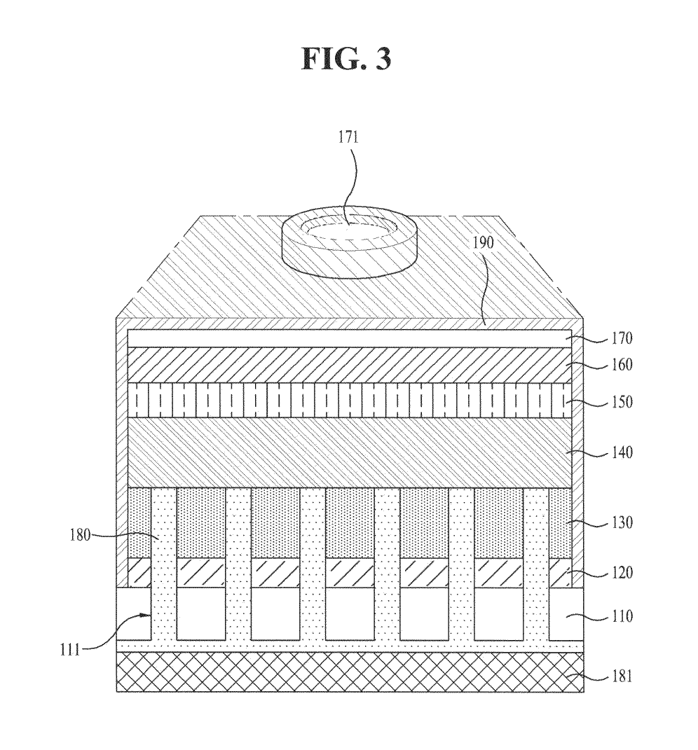

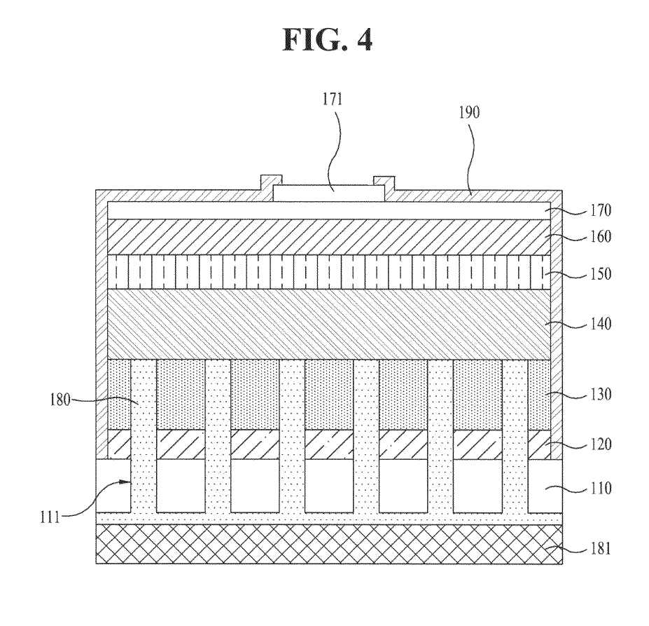

FIG. 3 is a perspective view illustrating a vertical light emitting diode according to the exemplary embodiment of the present invention, and FIG. 4 is a sectional view taken along the line A-A′ in FIG. 3. As illustrated in FIGS. 3 and 4, the vertical light emitting diode 100 according to the exemplary embodiment of the present invention includes a substrate 110 having a plurality of vertically penetrating via-holes 111, a first buffer layer 120 formed on the substrate 110 and having the plurality of via-holes 111, a plurality of nitride semiconductor layers 130 to 160 formed on the first buffer layer 120, a first electrode 170 made of a transparent conductive material and formed to contact an uppermost surface of the plurality of nitride semiconductor layers 130 to 160, a first electrode pad 171 formed to contact at least a part of the first electrode 170, a second electrode 180 formed as a filler in the plurality of via-holes 111 to contact a lower region of the plurality of nitride semiconductor layers 130 to 160, and a second electrode pad 181 made of a reflective metal and formed on a lower surface of the substrate 110 to contact the second electrode 181. In addition, a protective film 190 is formed to surround the plurality of nitride semiconductor layers 130 to 160, first electrode 170 and first electrode pad 171. The protective film 190 is made of a transparent insulating material and serves to electrically and physically protect the plurality of nitride semiconductor layers 130 to 160.

The substrate 110 can be made of sapphire (Al₂O₃) or silicon carbide (SiC). The substrate 110 has the plurality of via-holes 111 spaced apart from one another by a predetermined distance.

The first buffer layer 120 is formed on an upper surface of the substrate 110, more particularly, between the substrate 110 and the nitride semiconductor layers 130 to 160. The first buffer layer 120 can be made of silicon dioxide (SiO₂) having a similar structure to nitride semiconductors to enable appropriate growth of the nitride semiconductor layers 130 to 160 on the substrate 110. In this case, the first buffer layer 120 has the plurality of via-holes 111 penetrating the substrate 110 and contacts with the second electrode 180 through the plurality of via-holes 111.

The nitride semiconductor layers 130 to 160 are formed on the first buffer layer 120. The nitride semiconductor layers 130 to 160 include a second buffer layer 130 made of undoped nitride semiconductor (GaN), a first semiconductor layer 140 formed on the second buffer layer 130 and made of n-type nitride semiconductor, an active layer 150 formed on the first semiconductor layer 140 and having a multi-quantum-well (MQW) structure, and a second semiconductor layer 160 formed on the active layer 150 and made of p-type nitride semiconductor. The second buffer layer 130 has the plurality of via-holes 111 penetrating the substrate 110 to contact the second electrode 180 through the plurality of via-holes 111.

The second buffer layer 130, provided between the substrate 110 and the first semiconductor layer 140, serves to match different lattice constants and heat expansion coefficients between the substrate 110 and the first semiconductor layer 140 made of n-type nitride semiconductor (n-GaN). In particular, if undoped nitride semiconductor (corresponding to the second buffer layer 130) is first grown and n-type nitride semiconductor (corresponding to the first semiconductor layer 140) is grown thereon, the crystalline quality of n-type nitride semiconductor may be improved. The first semiconductor layer 140 can be made of n-type nitride semiconductor (n-GaN), which has conductivity due to a dopant such as silicon (Si). The active layer 150 has a MQW structure consisting of a barrier layer and well layer (InGaN-GaN). The wavelength band of light to be emitted from the light emitting diode is determined according to the composition ratio of nitride semiconductors (e.g., InGaN and GaN) in the active layer 150. The second semiconductor layer 160 is made of p-type nitride semiconductor (p-GaN), which has conductivity due to a dopant such as magnesium (Mg).

The first electrode 170 contacts the second semiconductor layer 160 made of p-type nitride semiconductor (p-GaN) and can be made of a transparent conductive material, such as zinc oxide (ZnO) or iridium tin oxide (ITO). The first electrode pad 171 can be made of any metal of Ni, Au, Pt, Ti and Al or an alloy containing thereof, and contacts at least a part of the first electrode 170.

The second electrode 180 contacts the lower region of the plurality of nitride semiconductor layers 130 to 160 exposed through the plurality of via-holes 111. In this case, the second electrode 180 contacts at least one of the second buffer layer 130 and the first semiconductor layer 140 made of n-type nitride semiconductor (n-GaN). Specifically, as illustrated in FIG. 4, the second electrode 180 may be formed as a filler in the plurality of via-holes 111 penetrating the substrate 110, first buffer layer 120 and second buffer layer 130, or may be formed as a filler in the plurality of via-holes 111 penetrating the substrate 110, or may be formed as a filler in the plurality of via-holes 111 penetrating the substrate 110 and first buffer layer 120. The second electrode 180 can be made of a metal such as Ti, Al, Ni, Au, Cr, Pt, V, In, Sn and Ag or an alloy containing thereof, and is filled in the plurality of via-holes 111. The second electrode pad 181 can be made of a reflective metal such as aluminum (Al), and is formed on the lower surface of the substrate 110 to contact the second electrode 180.

In the vertical light emitting diode having the above described configuration, the first electrode 170 and the second electrode 180 are formed in a vertical direction of the nitride semiconductor layers 130 to 160. This arrangement allows current flowing between the first electrode 170 and the second electrode 180 to be uniformly distributed rather than being concentrated on a certain region, resulting in uniform distribution of light power output throughout an upper surface of the vertical light emitting diode. Accordingly, the vertical light emitting diode may exhibit minimized static electricity generation and reduced forward voltage therein, and consequently, may have less deterioration and increased current efficiency. The first electrode 170 and second electrode 180 are separately formed at upper and lower sides of the nitride semiconductor layers 130 and 160. This makes it unnecessary to etch a part of the nitride semiconductor layers 130 to 160, thereby preventing a reduction in light emitting area. The second electrode pad 181, which is made of a reflective metal, may reflect light captured within the light emitting diode to emit the light outside, and thus, may improve the light output efficiency of the light emitting diode. In addition, heat generated in the nitride semiconductor layers 130 to 160 may be emitted outside through the metallic second electrode 180 as the second electrode 180 is formed in the plurality of via-holes 111 that occupy at least a partial region of the nitride semiconductor layers 130 to 160. This may improve heat emission efficiency of the light emitting diode, resulting in minimized deterioration and extended lifespan of the light emitting diode.

Hereinafter, as compared to the previously described related art light emitting diode in which the p-type electrode pad and n-type electrode pad are horizontally formed on the plurality of nitride semiconductor layers, experimental results with respect to electrical and optical characteristics of the vertical light emitting diode according to the exemplary embodiment of the present invention will be described.

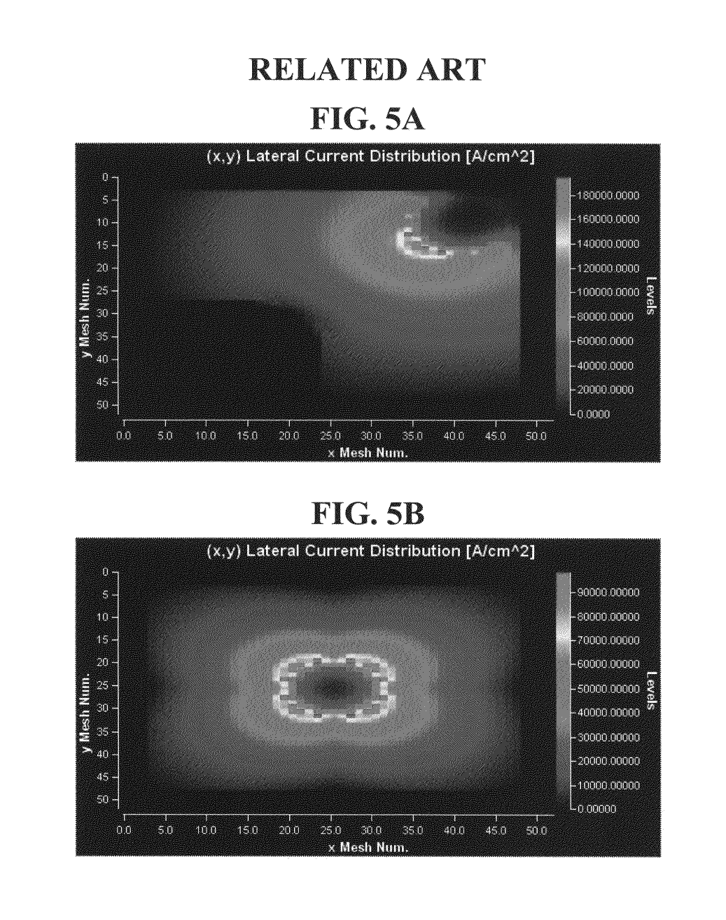

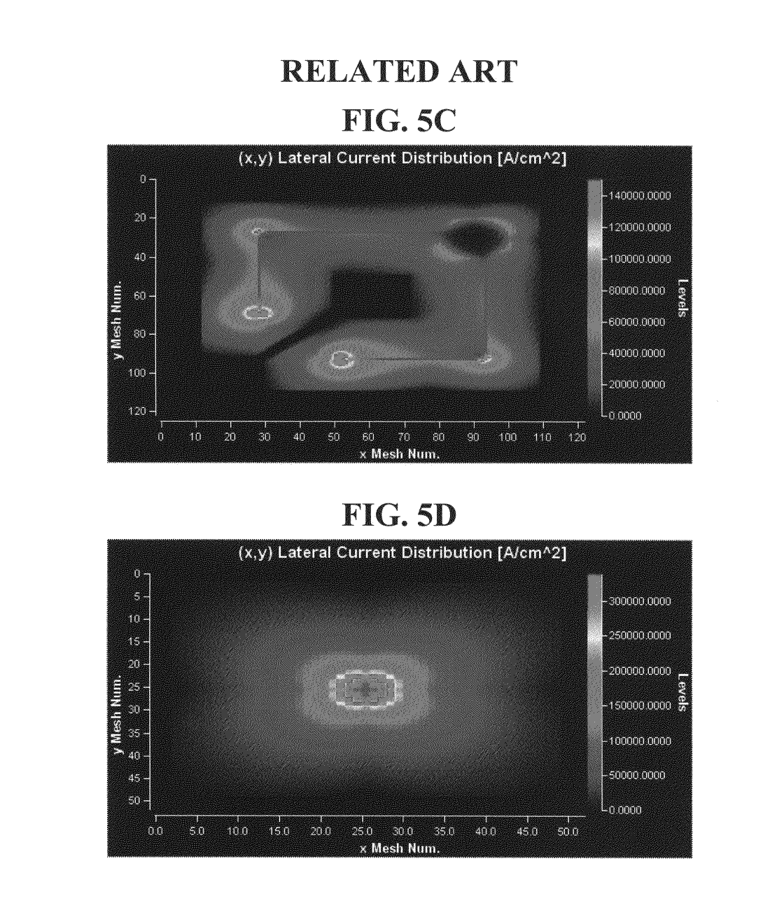

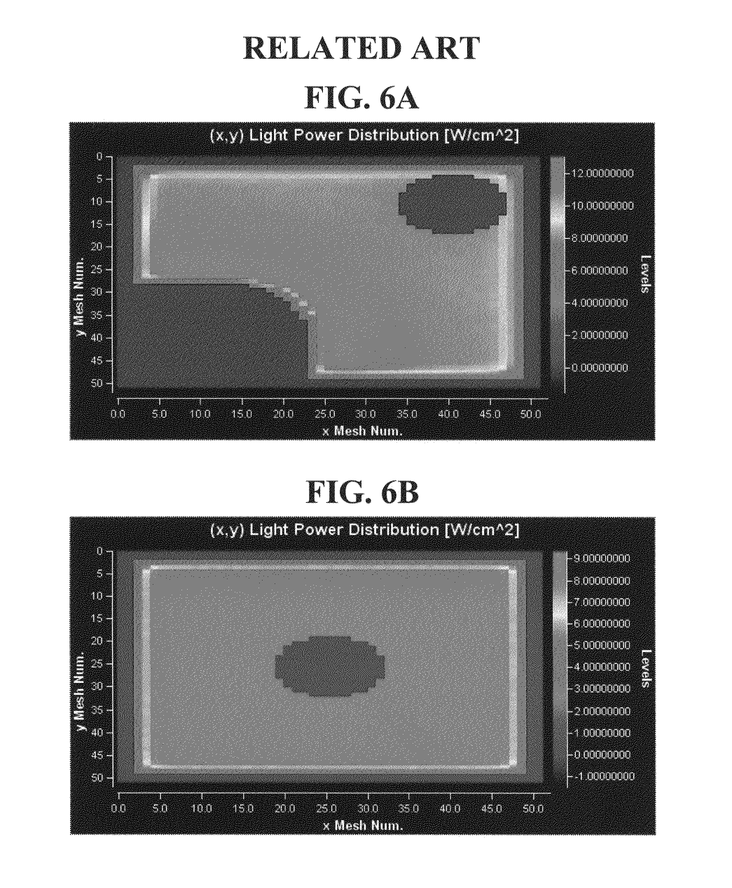

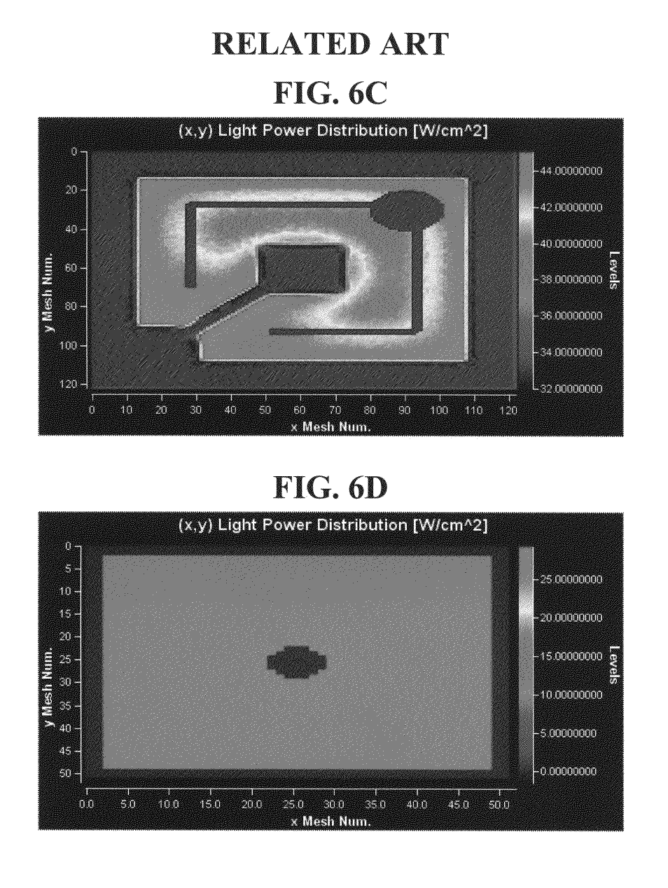

Table 1 illustrates experimental data comparing electrical and optical characteristics between the related art light emitting diode and the vertical light emitting diode according to the exemplary embodiment of the present invention. FIGS. 5A to 5D illustrate current distribution in the corresponding active layers of the related art light emitting diode and the vertical light emitting diode according to the exemplary embodiment of the present invention. FIGS. 6A to 6D illustrate light power output from the corresponding upper surfaces of the related art light emitting diode and the vertical light emitting diode according to the exemplary embodiment of the present invention.

TABLE 1

| | (A) | (B) | (C) | (D) |
|---|---|---|---|---|
| Size | 350 × 350 | 320 × 320 | 600 × 600 | 460 × 460 |
| Forward Voltage (V) | 3.252511 | 3.030676 | 3.186212 | 3.09769 |
| Applied current (mA) | 20.0006 | 20.0042 | 49.9968 | 50.0079 |
| Average Current | 23.8541 | 19.198 | 22.2329 | 23.5164 |
| Density (A/cm²) | | | | |
| Total Light Power (mW) | 8.40193 | 8.49191 | 53.201 | 58.1936 |
| Current Density of | 4.40595 | 2.96646 | 4.12368 | 1.07502 |
| Active Layer STD | | | | |
| (A/cm²) | | | | |

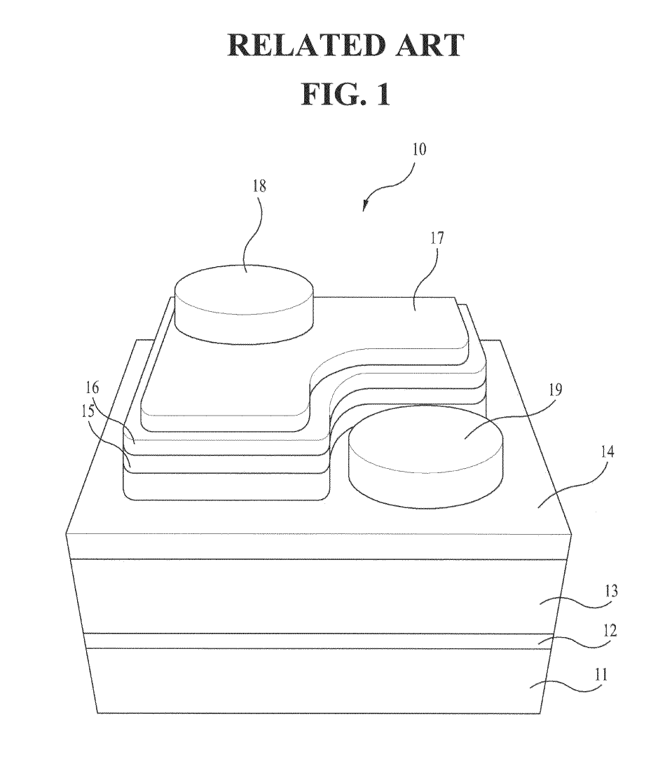

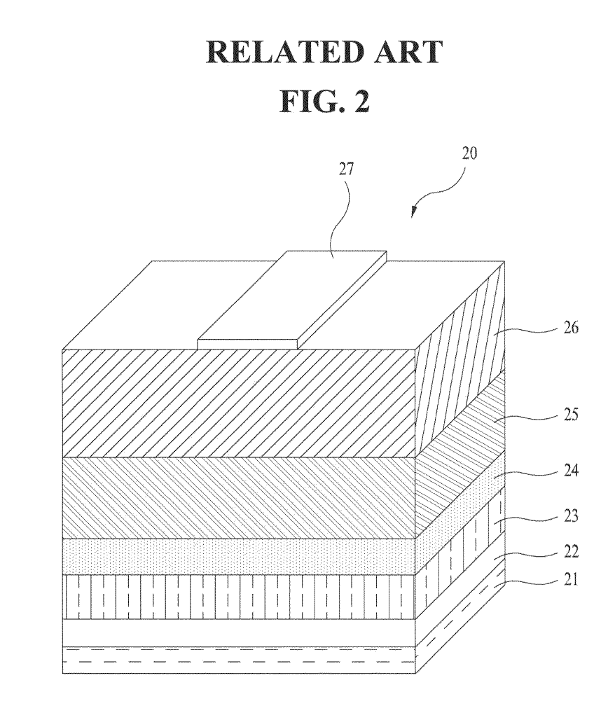

In Table 1, a light emitting diode A corresponds to the related art light emitting diode illustrated in FIG. 1 and has a size of 350×350. A light emitting diode B corresponds to the light emitting diode according to the exemplary embodiment of the present invention and has a size of 320×320. Although not illustrated, a light emitting diode C is a related art light emitting diode in which a p-type electrode is formed on nitride semiconductor layers to surround an n-type electrode pad, and has a size of 600×600. A light emitting diode D corresponds to the light emitting diode according to the exemplary embodiment of the present invention and has a size of 460×460. FIGS. 5A and 6A correspond to the light emitting diode A, FIGS. 5B and 6B correspond to the light emitting diode B, FIGS. 5C and 6C correspond to the light emitting diode C, and FIGS. 5D and 6D correspond to the light emitting diode D.

First, the light emitting diode A and light emitting diode B, which are small sized of 350×350 or less, will be compared with each other with reference to Table 1 and FIGS. 5A, 5B, 6A and 6B. In the case of the light emitting diode A, current in the active layer is concentrated on a partial region around the p-type electrode pad. On the other hand, in the case of the light emitting diode B, it can be observed from FIG. 5B that current in the active layer is uniformly distributed around the p-type electrode pad. This can also be observed from numerical values on Table 1. In the case of the light emitting diode A, the current density of the active layer is about 4.40 A/cm² and the average current density is about 23.85 A/cm² when the applied current is about 20 mA. On the other hand, in the case of the light emitting diode B, the current density of the active layer is about 2.96 A/m² lower than that of the light emitting diode A and the average current density is about 19.198 A/cm² lower than that of the light emitting diode A when the applied current is about 20 mA. As described above, the light emitting diode B has a lower current density than that of the light emitting diode A, and thus, has a lower forward voltage (about 3.03V) than the forward voltage (about 3.25V) of the light emitting diode A.

As illustrated in FIG. 6A, an upper surface of the light emitting diode A has no light power output at regions corresponding to the n-type electrode pad and p-type electrode pad. On the other hand, as illustrated in FIG. 6B, an upper surface of the light emitting diode B has uniform light power output except for a region corresponding to the p-type electrode pad. As represented in Table 1, the light power output of the light emitting diode A is about 8.40 mW, whereas the light power output of the light emitting diode B is about 8.49 mW higher than that of the light emitting diode A.

As described above, in the related art light emitting diode A and the vertical light emitting diode B according to the exemplary embodiment of the present invention which have a size of 350×350 or less, the light emitting diode B according to the exemplary embodiment of the present invention has a lower current density, reduced forward voltage, and increased light power output compared to the related art light emitting diode A.

Next, the light emitting diode C and light emitting diode D, which have sizes of 400×400 or more, will be compared with each other with reference to Table 1 and FIGS. 5C, 5D, 6C and 6D. In the case of the light emitting diode C, current in the active layer is concentrated on a region adjacent to the n-type electrode pad. On the other hand, in the case of the light emitting diode D, it can be observed from FIG. 5D that current in the active layer is uniformly distributed around the p-type electrode pad. This can also be observed from numerical values on Table 1. In the case of the light emitting diode C, the current density of the active layer is about 4.12 A/cm² and the average current density is about 22.23 A/cm² when the applied current is about 50 mA. On the other hand, in the case of the light emitting diode D having a size two thirds that of the light emitting diode C, the current density of the active layer is about 1.07 A/cm² lower than that of the light emitting diode C and the average current density is about 23.51 A/cm² similar to that of the light emitting diode C when the applied current is about 50 mA. The forward voltage of the light emitting diode D is about 3.09V lower than the forward voltage (about 3.18V) of the light emitting diode D.

In addition, as illustrated in FIG. 6C, an upper surface of the light emitting diode C has no light power output at regions corresponding to the n-type electrode pad and p-type electrode pad. On the other hand, as illustrated in FIG. 6D, an upper surface of the light emitting diode D has uniform light power output except for a region corresponding to the p-type electrode pad. In this way, as represented in Table 1, the light power output of the light emitting diode C is about 53.201 mW, whereas the light power output of the light emitting diode D is about 58.193 mW higher than that of the light emitting diode C.

As described above, in the related art light emitting diode C and the vertical light emitting diode D according to the exemplary embodiment of the present invention which have a size of 400×400 or more, the light emitting diode D according to the exemplary embodiment of the present invention has a lower current density, reduced forward voltage, and increased light power output compared to the related art light emitting diode C.

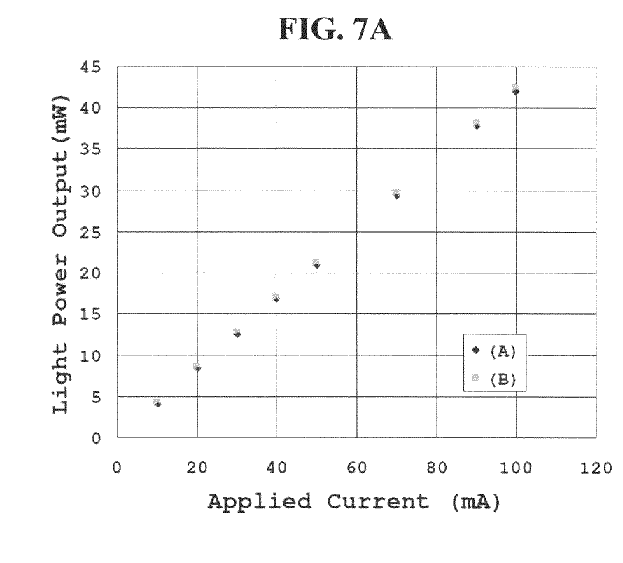

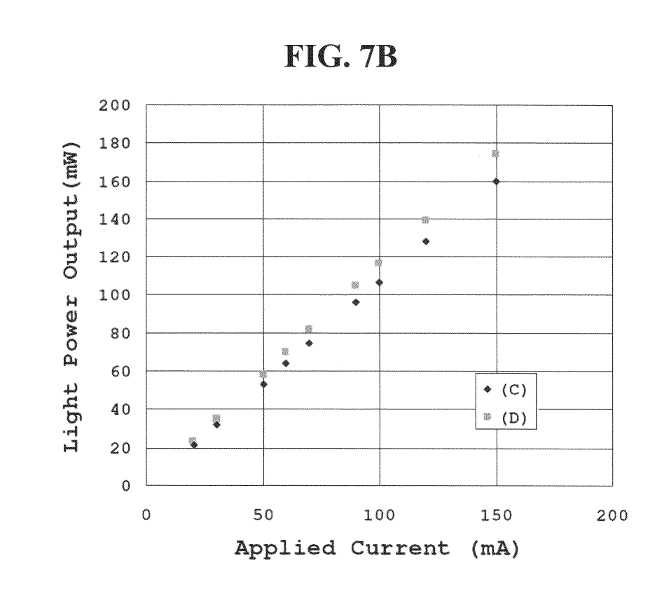

FIGS. 7A and 7B are graphs illustrating light power output based on the applied current in the related art light emitting diodes and the vertical light emitting diodes according to the exemplary embodiment of the present invention. Specifically, FIG. 7A is a graph illustrating variation of light power output based on the applied current in the light emitting diode A and light emitting diode B of Table 1, and FIG. 7B is a graph illustrating variation of light power output based on the applied current in the light emitting diode C and light emitting diode D of Table 1.

As illustrated in FIG. 7A, the light power output of the light emitting diode B is slightly greater than the light power output of the light emitting diode A with similar applied current. Also, as illustrated in FIG. 7B, the light power output of the light emitting diode D is greater than the light power output of the light emitting diode C with similar applied current. As described above, the light emitting diodes according to the exemplary embodiment of the present invention may achieve a brightness enhancement by 1˜10% over the related art light emitting diodes.

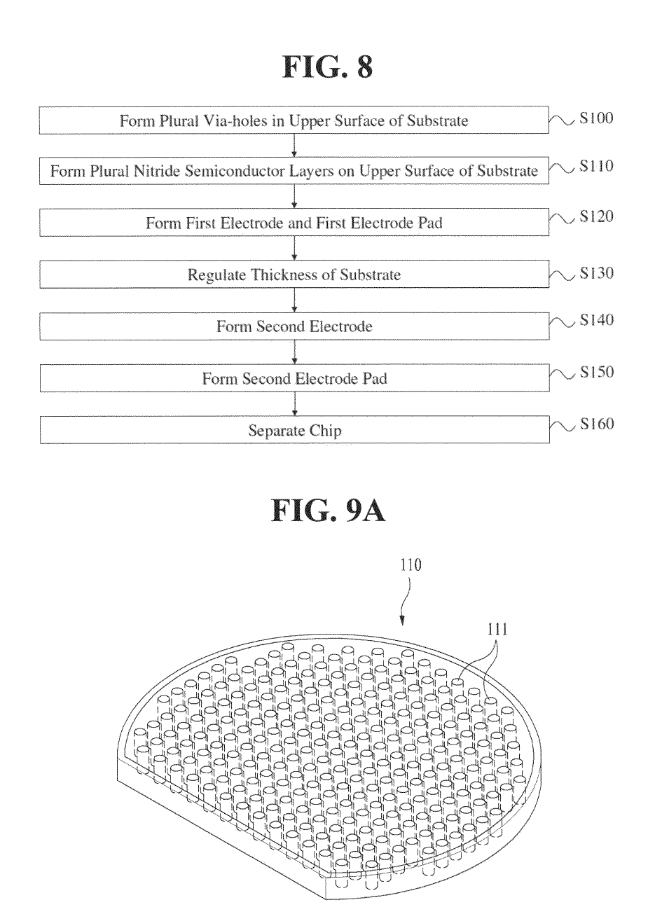

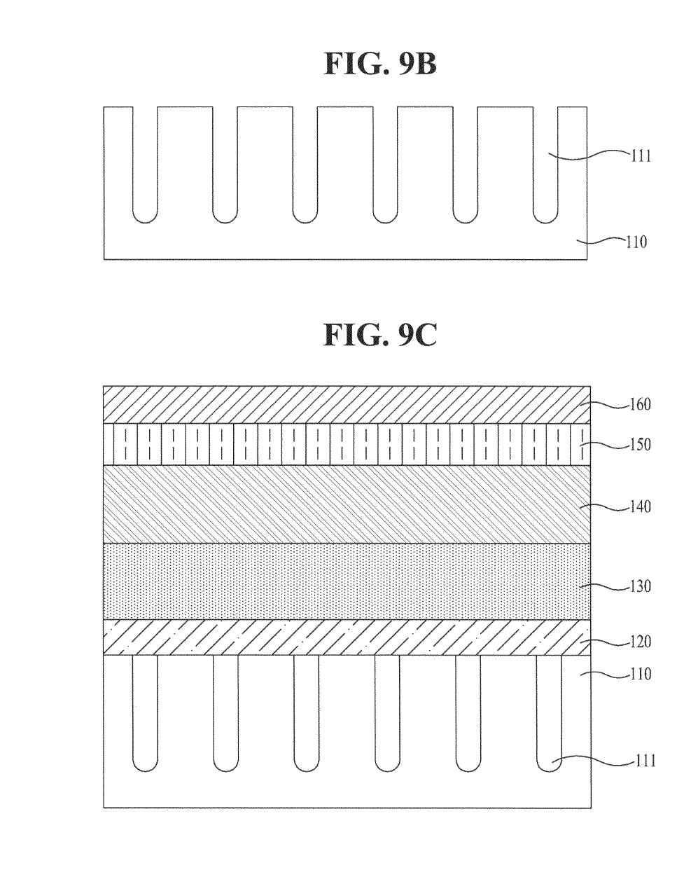

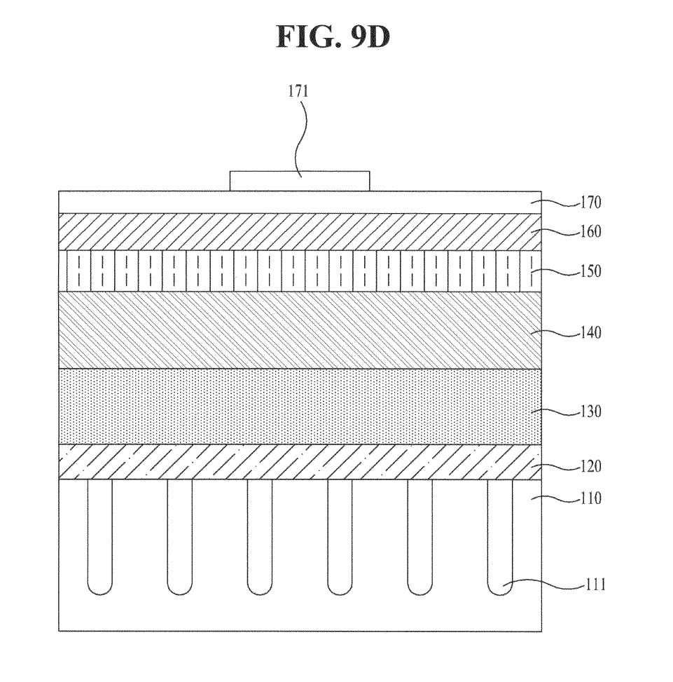

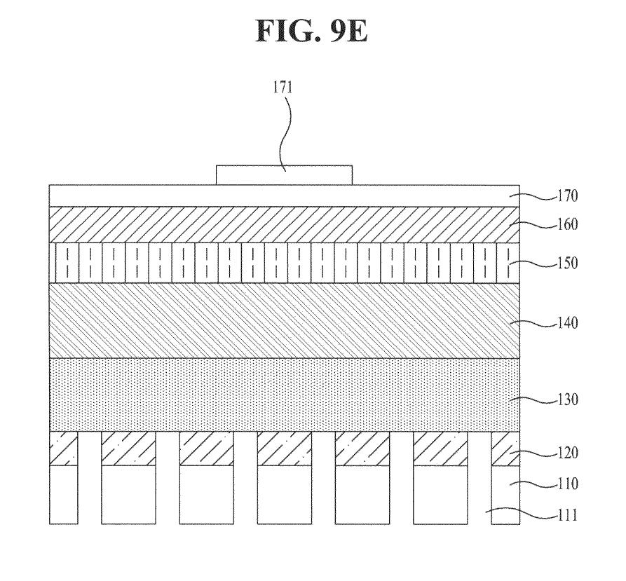

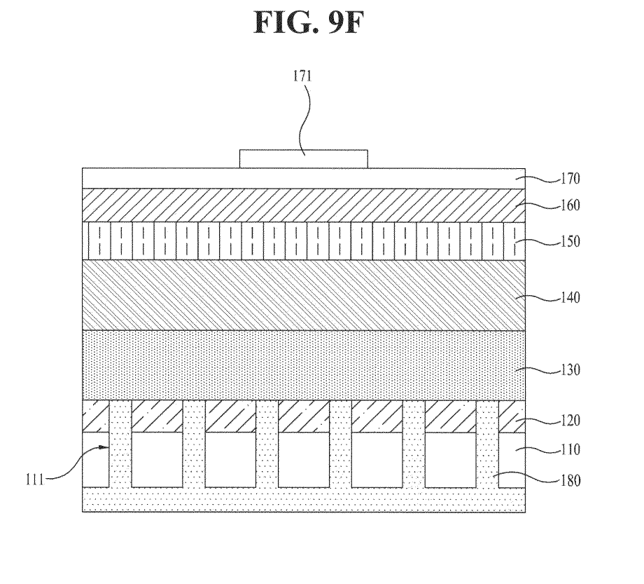

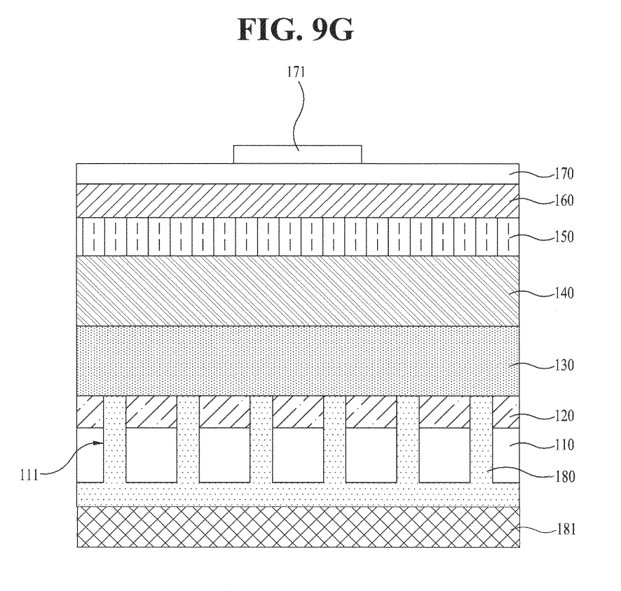

Hereinafter, a manufacturing method of the vertical light emitting diode according to the exemplary embodiment of the present invention will be described. FIG. 8 is a flow chart illustrating the manufacturing method of the vertical light emitting diode according to the exemplary embodiment of the present invention. FIGS. 9A to 9G are sectional views illustrating sequential processes of the manufacturing method of the vertical light emitting diode shown in FIG. 8.

The manufacturing method of the vertical light emitting diode according to the exemplary embodiment of the present invention, as illustrated in FIG. 8, includes forming the plurality of via-holes 111 in the upper surface of the substrate 110 (S100), forming a plurality of nitride semiconductor layers 130 to 160 on the substrate 110 having the plurality of via-holes 111 (S110), forming the first electrode 170 and first electrode pad 171 on the plurality of nitride semiconductor layers 130 to 160 (S120), regulating the thickness of the substrate 110 (S130), forming the second electrode 180 formed as a filler in the plurality of via-holes 111 to contact the lower region of the plurality of nitride semiconductor layers 130 to 160 exposed through the plurality of via-holes 111 (S140), forming the second electrode pad 181 using a reflective metal to contact the second electrode 180 formed on the lower surface of the substrate 110, and separating individual chips from one another.

In the exemplary operation (S100) for forming the plurality of via-holes 111 in the upper surface of the substrate 110, as illustrated in FIGS. 9A and 9B, the plurality of via-holes 111 are formed in the upper surface of the substrate 110 in the form of a wafer made of sapphire (Al₂O₃) or silicon carbide (SiC) such that the via-holes 111 are spaced apart from one another by a predetermined distance. More specifically, a pattern mask is formed on the upper surface of the wafer substrate 110 having the thickness of about 430 μm. The upper surface of the wafer substrate 110 is subjected to etching using the pattern mask such that the plurality of via-holes 111 having a diameter of 30˜70 μm and a depth of 150˜250 μm are spaced apart from one another by a distance of 30˜100 μm. In this case, the plurality of via-holes 111 are formed so as not to penetrate the substrate 110.

The pattern mask is a photo mask or a metal mask including a pattern in which holes having a diameter of 30˜70 μm are spaced apart from one another by a distance of 30˜100 μm. The etching of the wafer substrate 110 may be performed by dry etching, such as laser drilling or RIE-ICP, or wet etching. In particular, when the wafer substrate 110 is etched by laser drilling, a laser having a wavelength band of 193˜248 nm is irradiated to the upper surface of the wafer substrate 110 on which the pattern mask has been formed.

The thickness of the wafer substrate 110, the shape, diameter and distance of the via-holes 111, the wavelength band of a laser in the laser drilling etching, and the like as mentioned above are given only by way of example for the sake of better description of the exemplary embodiment of the present invention, and of course, the embodiment of the present invention may be applied in other manners rather than the above mentioned manner. In particular, although FIGS. 9A and 9B illustrate the via-holes 111 as having a circular column shape, the via-holes 111 may alternatively have a polygonal, elliptical, parallelogram, and various other cross sections, and also may have any one of cylindrical, conical, inverted conical, pyramidal and various other shapes.

As illustrated in FIG. 9C, the first buffer layer 120 and the plurality of nitride semiconductor layers 130 to 160 are formed on the substrate 111 in which the plurality of via-holes 111 have been formed. In this case, the plurality of nitride semiconductor layers 130 to 160 may be grown on the upper surface of the substrate 110 using a metal organic chemical vapor deposition (MOCVD) method, liquid phase epitaxy method, hydride vapor phase epitaxy method, molecular beam epitaxy method, or the like. The plurality of nitride semiconductor layers 130 to 160 are grown on the upper surface of the substrate 110 using the MOCVD method. For example, among the plurality of nitride semiconductor layers 130 to 160, the second buffer layer 130 may be made of undoped nitride semiconductor (GaN) to have the thickness of 0.5˜2.0 μm, and the first semiconductor layer 140 may be made of Si-doped n-type nitride semiconductor (n-GaN) to have the thickness of 2.0 μm or less. The active layer 150 may be made of nitride semiconductor (InGaN-GaN) having a MQW structure consisting of five layers, and the second semiconductor layer 160 may be made of Mg-doped p-type nitride semiconductor (p-GaN) to have a thickness of 0.2 μm or less.

As illustrated in FIG. 9D, in the operation (S120) for forming the first electrode 170 and first electrode pad 171, the first electrode 170 is formed on the second semiconductor layer 160 using a transparent conductive material, such as ZnO or ITO. The first electrode pad 171 is formed to contact at least a part of the first electrode 170. In this case, the first electrode pad 171 may be made of a metal such as Ni, Au, Pt, Ti and Al or an alloy containing thereof.

The operation (S130) for regulating the thickness of the substrate 110 includes reducing the thickness of the substrate 110 by lapping and polishing the lower surface of the substrate 110 such that the plurality of via-holes 111 penetrate the substrate 110, and regulating the depth of the plurality of via-holes 111 such that the plurality of via-holes 111 penetrating the substrate 110 is formed in at least one of the plurality of nitride semiconductor layers 130 to 160.

As illustrated in FIG. 9E, in the operation for reducing the thickness of the substrate 110, lapping and polishing processes are performed on the lower surface of the substrate 110 such that the thickness of the substrate 110 is reduced to 200 μm or less. Then, in the operation for regulating the depth of the plurality of via-holes 111, the plurality of via-holes 111 penetrating the substrate 110 is further deeply formed to extend into the nitride semiconductor layers 130 to 160, more particularly, into at least one of the second buffer layer 130 and first semiconductor layer 140. For example, the lower surface of the substrate 110, the thickness of which has been reduced, may be subjected to plasma etching such that the plurality of via-holes 111 exposes the first semiconductor layer 140 or only the second buffer layer 130. In this case, the depth of the plurality of via-holes 111 may be freely determined by a diode designer considering characteristics of the light emitting diode.

As illustrated in FIG. 9F, in the operation (S140) for forming the second electrode 180, the second electrode 180 may be formed by filling any metal of Ti, Al, Ni, Au, Cr, Pt, V, In, Sn and Ag or an alloy containing thereof, in the plurality of via-holes 111 penetrating at least one of the substrate 110, first buffer layer 120, and second buffer layer 130. Specifically, the second electrode 180 corresponds to the metal or the alloy filled in the plurality of via-holes 111. In this case, according to the depth of the plurality of via-holes 111, the second metal 180 may contact only the second buffer layer 130, or may contact the second buffer layer 130 and first semiconductor layer 140. The second electrode 180 may be made of a metal having high heat conductivity, or may be made of a metal having high reflectivity, such as Al.

As illustrated in FIG. 9G, in the operation (S150) for forming the second electrode pad 181, the second electrode pad 181 is formed on the lower surface of the substrate 110 using a reflective metal to contact the second electrode 180. In this case, the second electrode pad 181 may be formed by vapor depositing Aluminum (Al) or copper (Cu) on the lower surface of the substrate 110.

In the operation (S160) for separating individual chips from one another, breaking is performed to separate individual chips from one another after forming a scribing line using a laser or diamond.

As described above, the manufacturing method of the vertical light emitting diode according to the exemplary embodiment of the present invention does not include an operation for removing the substrate 110 used for the growth of the nitride semiconductor layers 130 to 160, such as a laser lift off (LLO) operation. Accordingly, the manufacturing method may be simplified and the overall manufacturing time may be reduced. Further, elimination of the LLO operation may prevent damage to the plurality of nitride semiconductor layers and thus, the yield of the light emitting diode may be enhanced. Furthermore, the overall manufacturing costs may be reduced by not using expensive LLO equipment.

As is apparent from the above description, a vertical light emitting diode according to an exemplary embodiment of the present invention includes a substrate having a plurality of via-holes, a plurality of nitride semiconductor layers formed on an upper surface of the substrate, a first electrode formed on the plurality of nitride semiconductor layers, a first electrode pad formed to contact at least a part of the first electrode, a second electrode formed as a filler in the plurality of via-holes to contact the lower region of the plurality of nitride semiconductor layers exposed through the plurality of via-holes penetrating the substrate, and a second metal pad made of a reflective metal and formed on a lower surface of the second electrode. In this case, the plurality of via-holes does not penetrate the substrate during the growth of the plurality of nitride semiconductor layers. The thickness of the substrate is regulated prior to forming the second electrode such that the plurality of via-holes penetrate the substrate. The vertical light emitting diode and the manufacturing method of the same according to the present invention may have the following benefits.

First, the first electrode and second electrode are formed respectively at upper and lower sides of the plurality of nitride semiconductor layers, thereby preventing a reduction in light emitting area.

Second, since the first electrode and second electrode are formed in a vertical direction, it may be possible to allow current flowing between the first electrode and the second electrode to be uniformly distributed rather than being concentrated on a certain region unlike the related art light emitting diode. This may increase current efficiency due to a reduced forward voltage and further prevent generation of static electricity and deterioration of the light emitting diode.

Third, when using the substrate in which the plurality of via-holes has, been formed, the manufacturing method has no need for an operation for removing the substrate used for the growth of the plurality of nitride semiconductor layers. Thus, it may be possible to prevent damage to the plurality of nitride semiconductor layers due to a laser lift off process that has been used to remove the substrate in the related art. Therefore, it may be possible to increase the yield of the light emitting diode.

Fourth, the second electrode pad, which is made of a reflective metal and is formed on the lower surface of the substrate, may act to reflect light generated in the plurality of nitride semiconductor layers so as to emit the light outside, resulting in enhanced light output efficiency.

Fifth, heat generated from the plurality of nitride semiconductor layers may be easily emitted outside through the plurality of via-holes in which the metal having a high heat conductivity is filled because the second electrode is formed as a filler in the plurality of via-holes formed in the substrate and at least one of the plurality of nitride semiconductor layers. As a result, the light emitting diode may have enhanced heat emission efficiency without a risk of deterioration, and thus, may have an extended lifespan.

Sixth, as the plurality of via-holes is filled with the metal, it may be possible to prevent deterioration in the durability of the light emitting diode due to the plurality of via-holes.

It will be apparent to those skilled in the art that various modifications and variations can be made in the vertical light emitting diode and the manufacturing method of the same of the present invention without departing from the spirit or scope of the invention. Thus, it is intended that the present invention cover the modifications and variations of this invention provided they come within the scope of the appended claims and their equivalents.

What is claimed is:

1. A vertical light emitting diode, comprising:
a substrate having a plurality of penetrating via-holes,
a plurality of nitride semiconductor layers formed on the substrate,
a first electrode formed on the plurality of nitride semiconductor layers, and
a second electrode formed to fill the plurality of via-holes thereby contacting part of the plurality of nitride semiconductor layers.

2. The vertical light emitting diode in claim 1, further comprising a first buffer layer formed on an upper surface of the substrate.

3. The vertical light emitting diode in claim 1, wherein the plurality of nitride semiconductor layers include a second buffer layer, a first semiconductor layer formed on the second buffer layer, an active layer formed on the first semiconductor layer, and a second semiconductor layer formed on the active layer.

4. The vertical light emitting diode in claim 3, wherein the second buffer layer is made of undoped nitride semiconductor.

5. The vertical light emitting diode in claim 3, wherein the first semiconductor layer is made of n-type nitride semiconductor.

6. The vertical light emitting diode in claim 3, wherein the active layer has a multi-quantum-well structure.

7. The vertical light emitting diode in claim 3, wherein the second semiconductor layer is made of p-type nitride semiconductor.

8. The vertical light emitting diode in claim 3, wherein the second buffer layer has a plurality of via-holes.

9. The vertical light emitting diode in claim 1, wherein the first electrode is formed using a transparent conductive material.

10. The vertical light emitting diode in claim 1, wherein the first electrode is formed of ZnO or ITO.

11. The vertical light emitting diode in claim 1, wherein the substrate is made of Al₂O₃ or SiC.

12. The vertical light emitting diode in claim 1, wherein the second electrode includes one or more of Ti, Al, Ni, Au, Cr, Pt, V, In, Sn, and Ag.

13. The vertical light emitting diode in claim 1, further comprising a first electrode pad formed to contact the first electrode and a second electrode pad formed to contact the second electrode.

14. The vertical light emitting diode in claim 13, wherein the first electrode pad includes Ni, Au, Pt, Ti, or Al.

15. The vertical light emitting diode in claim 13, wherein the second electrode pad is formed of a reflective metal.

16. The vertical light emitting diode in claim 1, wherein the plurality of via-holes have one of circular, polygonal, elliptical, and parallelogram cross sections.

17. The vertical light emitting diode in claim 1, wherein the plurality of via-holes have one of cylindrical, conical, inverted conical, and pyramidal shapes.

18. A method of manufacturing a vertical light emitting diode, comprising:
forming a plurality of via-holes in a substrate,
forming a plurality of nitride semiconductor layers on the substrate,
forming a first electrode and a first electrode pad on the plurality of nitride semiconductor layers, and
forming a second electrode in the plurality of via-holes to contact part of the plurality of nitride semiconductor layers exposed through the plurality of via-holes.

19. The method of claim 18, further comprising forming a second electrode pad using a reflective metal to contact the second electrode.

20. The method of claim 18, wherein the plurality of via-holes are formed in an upper surface of the substrate such that the via-holes are spaced apart from one another by 30˜100 μm.

21. The method of claim 18, wherein the plurality of via-holes have a diameter of 30˜70 μm and a depth of 150˜250 μm.

22. The method of claim 18, wherein the plurality of via-holes have one of circular, polygonal, elliptical, and parallelogram cross sections.

23. The method of claim 18, wherein the plurality of via-holes have one of cylindrical, conical, inverted conical, and pyramidal shapes.

24. The method of claim 18, further comprising forming a first buffer layer on the substrate in which the plurality of via-holes have been formed.

25. The method of claim 18, further comprising reducing a thickness of the substrate by lapping and polishing a lower surface of the substrate such that the plurality of via-holes penetrate the substrate.

26. The method of claim 18, further comprising regulating a depth of the plurality of via-holes such that the plurality of via-holes penetrating the substrate is formed in at least one of the plurality of nitride semiconductor layers.

27. The method of claim 18, further comprising forming a second electrode in the plurality of via-holes.

28. The method of claim 18, further comprising separating individual chips from one another after forming a scribing line using a laser or diamond.

29. The method of claim 18, wherein the plurality of nitride semiconductor layers include a second buffer layer, a first semiconductor layer formed on the second buffer layer, an active layer formed on the first semiconductor layer, and a second semiconductor layer formed on the active layer.

30. The method of claim 29, wherein the second buffer layer is made of undoped nitride semiconductor.

31. The method of claim 29, wherein the first semiconductor layer is made of n-type nitride semiconductor.

32. The method of claim 29, wherein the active layer has a multi-quantum-well structure.

33. The method of claim 29, wherein the second semiconductor layer is made of p-type nitride semiconductor.

34. The method of claim 29, wherein the second buffer layer has a plurality of via-holes.

35. The method of claim 18, wherein the first electrode is formed using a transparent conductive material.

36. The method of claim 18, wherein the first electrode is formed of ZnO or ITO.

37. The method of claim 18, wherein the substrate is made of Al₂O₃ or SiC.

38. The method of claim 18, wherein the second electrode includes one or more of Ti, Al, Ni, Au, Cr, Pt, V, In, Sn, and Ag.

39. The method of claim 18, wherein the first electrode pad includes Ni, Au, Pt, Ti, or Al.
